(19) United States
(12) Patent Application Publication
(10) Pub. No.: US 2023/0203706 A1
(43) Pub. Date: Jun. 29, 2023

(54) EPITAXIAL REACTOR SYSTEMS AND METHODS OF USING SAME

(71) Applicant: ASM IP Holding B.V., Almere (NL)

(72) Inventors: Alexandros Demos, Scottsdale, AZ (US); Hichem M'Saad, Paradise Valley, AZ (US); Xing Lin, Chandler, AZ (US); Caleb Miskin, Mesa, AZ (US); Shivaji Peddeti, Phoenix, AZ (US); Amir Kajbafvala, Chandler, AZ (US)

(21) Appl. No.: 18/086,734

(22) Filed: Dec. 22, 2022

Related U.S. Application Data
(60) Provisional application No. 63/293,246, filed on Dec. 23, 2021.

(51) Int. Cl. C30B 25/14; C30B 25/12; C30B 25/16; C30B 25/18; C30B 29/06; C30B 29/08

(52) U.S. Cl. CPC C30B 25/14; C30B 25/12; C30B 25/165; C30B 25/186; C30B 29/06; C30B 29/08

(57) ABSTRACT

A reactor system may comprise a first reaction chamber and a second reaction chamber. The first and second reaction chambers may each comprise a reaction space enclosed therein, a susceptor disposed within the reaction space, and a fluid distribution system in fluid communication with the reaction space. The susceptor in each reaction chamber may be configured to support a substrate. The reactor system may further comprise a first reactant source, wherein the first reaction chamber and the second reaction chamber are fluidly coupled to the first reactant source at least partially by a first reactant shared line. The reactor system may be configured to deliver a first reactant from the first reactant source to the first reaction chamber and a second reaction chamber through the first reactant shared line.

### CROSS-REFERENCE TO RELATED APPLICATIONS

This application is a non-provisional of, and claims priority to and the benefit of, U.S. Provisional Pat. Application No. 63/293,246, filed Dec. 23, 2021 and entitled “EPITAXIAL REACTOR SYSTEMS AND METHODS OF USING SAME,” which is hereby incorporated by reference herein.

### FIELD OF THE DISCLOSURE

The present disclosure relates generally to methods and systems for semiconductor processing and reactor systems having multiple processing chambers.

### BACKGROUND OF THE DISCLOSURE

Semiconductor processing, including chemical vapor deposition (CVD), is a well-known process for forming thin films of materials on substrates, such as silicon wafers. In a CVD process, for example, gaseous molecules of the material to be deposited are supplied to substrates to form a thin film of that material on the substrates by chemical reaction. Such formed thin films may be polycrystalline, amorphous, or epitaxial.

During a typical CVD process, one or more substrates are placed on a substrate support (e.g., a susceptor) inside a chamber within the reactor. Both the substrate and the substrate support are typically heated to a desired temperature. In a typical substrate deposition step, reactant gases are passed over the heated substrate causing deposition of a thin layer of a desired material on the substrate surface. If the deposited layer has the same crystallographic structure as an underlying silicon surface, the deposited layer is called an epitaxial layer (or a monocrystalline). Through subsequent processes, these layers may be used to form a semiconductor device, such as an integrated circuit.

Typically, CVD processes are conducted at elevated temperatures to accelerate the chemical reaction and to produce high quality films, with some of these processes, such as epitaxial silicon deposition, being conducted at extremely high temperatures (e.g., greater than 900° C.). However, if depositing layers on top of previously-deposited layers, such high temperatures may degrade previously-deposited layers and/or the crystal lattice between layers, causing defects in the layers and resulting devices.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Disclosed herein, according to various embodiments, is a reactor system or apparatus for use in semiconductor processing such as chemical vapor deposition (CVD) and other deposition steps. In various embodiments, a reactor system may comprise a first reaction chamber and a second reaction chamber. The first and second reaction chambers may each comprise a reaction space enclosed therein, a susceptor disposed within the reaction space, and a fluid distribution system in fluid communication with the reaction space. The susceptor in each reaction chamber may be configured to support a respective substrate. The reactor system may further comprise a first reactant source, wherein the first reaction chamber and the second reaction chamber are fluidly coupled to the first reactant source at least partially by a first reactant shared line. The reactor system may be configured to deliver a first reactant (e.g., a first epitaxial semiconductor reactant) from the first reactant source to the first reaction chamber and a second reaction chamber through the first reactant shared line. In various embodiments, the first susceptor and the second susceptor can comprise a ceramic material. In various embodiments, the first susceptor and the second susceptor can each comprise an electric heater. In various embodiments, the first susceptor and the second susceptor can each comprise a first heater in a first susceptor portion and a second heater in a second susceptor portion, such that the first susceptor and the second susceptor can comprise dual-zone heaters. In various embodiments, the first fluid distribution system and the second fluid distribution system comprise at least one of aluminum, quartz, stainless steel, or nickel.

In various embodiments, the reactor system can further comprise a remote plasma unit in fluid communication with the first reaction chamber and the second reaction chamber, wherein the remote plasma unit can be configured to deliver an activated species to the first reaction chamber and a second reaction chamber through a shared plasma line. In various embodiments, the reactor system can further comprise a second epitaxial semiconductor reactant source, wherein the first reaction chamber and the second reaction chamber can be fluidly coupled to the second epitaxial semiconductor reactant source at least partially by a second reactant shared line. In various embodiments, the first fluid distribution system and the second fluid distribution system can each comprise a first channel fluidly coupled to the first epitaxial semiconductor reactant source and a second channel fluidly coupled to the second epitaxial semiconductor reactant source, wherein the first channel and the second channel can be fluidly separate. In various embodiments, the remote plasma unit can be fluidly coupled to the first channel and the second channel in each of the first fluid distribution system and the second fluid distribution system. In various embodiments, the second channel comprises a greater number of holes at an outer portion of each of the first fluid distribution system and the second fluid distribution system than the first channel.

In various embodiments, the first epitaxial semiconductor reactant source can be a silicon-containing epitaxial semiconductor reactant source configured to deliver a silicon precursor to the first reaction chamber and the second reaction chamber, and the second epitaxial semiconductor reactant source can be a germanium-containing epitaxial semiconductor reactant source configured to deliver a germanium precursor to the first reaction chamber and the second reaction chamber. In various embodiments, the silicon precursor can comprise at least one of a hydrogenated silicon precursor or a chlorinated silicon precursor. In various embodiments, the germanium precursor can comprise at least one of germane (GeH₄), digermane (Ge₂H₆), trigermane (Ge₃H₈), or germylsilane (GeH₆Si).

In various embodiments, the reactor system can further comprise a controller; and a tangible, non-transitory memory configured to communicate with the controller, the tangible, non-transitory memory having instructions stored thereon that, in response to execution by the controller, cause the controller to perform operations. Such operations can comprise flowing, by the controller, a first epitaxial semiconductor reactant from the first epitaxial semiconductor reactant source to the first reaction chamber and the second reaction chamber via the first reactant shared line; flowing, by the controller, a second epitaxial semiconductor reactant from the second epitaxial semiconductor reactant source to the first reaction chamber and the second reaction chamber via the second reactant shared line; forming a first epitaxial layer on the first substrate; and/or forming a second epitaxial layer on the second substrate.

In various embodiments, a method can comprise performing a multilayer deposition process on a first substrate in a first reaction chamber and on a second substrate in a second reaction chamber, wherein the first reaction chamber and the second reaction chamber are comprised in a reactor. The multilayer deposition process can comprise steps, including flowing a first epitaxial semiconductor reactant from a first epitaxial semiconductor reactant source to the first reaction chamber and the second reaction chamber through a first reactant shared line fluidly coupling the first epitaxial semiconductor reactant source to the first reaction chamber and the second reaction chamber; flowing a second epitaxial semiconductor reactant from a second epitaxial semiconductor reactant source to the first reaction chamber and the second reaction chamber through a second reactant shared line fluidly coupling the second epitaxial semiconductor reactant source to the first reaction chamber and the second reaction chamber; forming a first epitaxial layer on the first substrate and on the second substrate; and/or forming a second epitaxial layer on the first substrate and on the second substrate. In various embodiments, forming the first epitaxial layer can occur in response to the flowing the first epitaxial semiconductor reactant and the flowing the second epitaxial semiconductor reactant to the first reaction chamber and the second reaction chamber. The first epitaxial semiconductor reactant can comprise a silicon precursor. The second epitaxial semiconductor reactant can comprise a germanium precursor. The first epitaxial layer can comprise a silicon-germanium layer.

In various embodiments, forming the second epitaxial layer can occur in response to flowing the first epitaxial semiconductor reactant to the first reaction chamber and the second reaction chamber separately from the flowing the second epitaxial semiconductor reactant to the first reaction chamber and the second reaction chamber. The first epitaxial semiconductor reactant can comprise the silicon precursor. The second epitaxial layer can comprise a silicon layer.

In various embodiments, the multilayer deposition process can be repeated a plurality of times, for example, at least 32 times. In various embodiments, the method can further comprise flowing a cleaning compound from a remote plasma unit to the first reaction chamber and the second reaction chamber, wherein the remote plasma unit is fluidly coupled to the first reaction chamber and the second reaction chamber at least partially by a shared plasma line, and wherein the flowing the cleaning compound occurs after the multilayer deposition process is repeated the plurality of times. In various embodiments, the method can further comprise precleaning the first substrate in the first reaction chamber; heating a first susceptor within the first reaction chamber to a temperature between 475° C. and 550° C., wherein the first susceptor supports the first substrate; and/or heating a second susceptor within the second reaction chamber to a temperature between 475° C. and 550° C., wherein the second susceptor supports the second substrate.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1A depicts a schematic diagram of an exemplary reactor system, in accordance with various embodiments.

FIGS. 1B-1E illustrate exemplary reactor systems, in accordance with various embodiments.

FIG. 2 depicts a schematic diagram of an exemplary reactor system, in accordance with various embodiments.

FIG. 3 depicts a cross-sectional view of a reaction chamber, in accordance with various embodiments.

FIG. 4 depicts a schematic diagram of a reaction chamber, in accordance with various embodiments.

FIG. 5 depicts a bottom surface of a gas distribution apparatus, in accordance with various embodiments.

FIG. 6 depicts a method of depositing material layers on substrates, in accordance with various embodiments.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The detailed description of various embodiments herein makes reference to the accompanying drawings, which show various embodiments by way of illustration. While these various embodiments are described in sufficient detail to enable those skilled in the art to practice the disclosure, it should be understood that other embodiments may be realized and that logical, chemical, and mechanical changes may be made without departing from the scope of the disclosure. Thus, the detailed description herein is presented for purposes of illustration only and not of limitation. For example, the steps recited in any of the method or process descriptions may be executed in any workable order and are not necessarily limited to the order presented. Furthermore, any reference to singular includes plural embodiments, and any reference to more than one component or step may include a singular component or step. Also, any reference to attached, fixed, coupled, connected, or the like may include permanent, removable, temporary, partial, full, and/or any other possible attachment option. It is to be understood that unless specifically stated otherwise, references to “a,” “an,” and/or “the” may include one or more than one and that reference to an item in the singular may also include the item in the plural.

As used herein, the terms “wafer” and “substrate” may be used interchangeably to refer to any underlying material or materials that may be used, or upon which, a device, a circuit, or a film may be formed.

As used herein, the term “chemical vapor deposition” (CVD) may refer to any process wherein a substrate is exposed to one or more volatile precursors, which react and/or decompose on a substrate surface to produce a desired deposition.

Reactor systems described herein may be used for a variety of applications, including depositing, etching, and/or cleaning materials on a substrate surface. By way of particular examples, the reactor systems can be used for CVD and/or cyclical processes, such as an epitaxial deposition process. Reactor systems may comprise one or more modules, at least one of which can comprise multiple reaction chambers configured to process one or more substrates to deposit material thereon. For example, processing of a substrate may occur in one reaction chamber (i.e., multiple steps occurring in such reaction chamber), or such a substrate may be transferred between reaction chambers (e.g., of the same module) for different processing steps.

As device and chip sizes get smaller, the capacity to form more chips (e.g., semiconductor chips) from a substrate or wafer (i.e., increase chip output per substrate or wafer) has become limited. Therefore, rather than expanding the surface area of a substrate upon which to deposit epitaxial layers (for use as semiconductors), or increasing the number of chips able to be taken from such surface area, epitaxial layers may be stacked on top of one another. Thus, the semiconductor chip output from a substrate may be increased by vertically expanding the number of epitaxial layers deposited on the substrate.

Stacking epitaxial layers on a substrate, however, may cause processing temperature limitations. Typically, processes forming epitaxial layers, such as CVD processes, are conducted at elevated temperatures (e.g., greater than 900° C.) to accelerate deposition. However, in response to stacking epitaxial layers, such elevated temperatures may degrade or decompose the previously-deposited layers upon which subsequent epitaxial layers will be deposited. Accordingly, lower processing temperatures for epitaxial layer deposition upon previously-deposited layers may be used to maintain the quality and integrity of such previously-deposited layers. Such lower processing temperatures, however, may decrease output of a reactor system because processing (e.g., material deposition on a substrate) occurs more slowly at such relatively lower temperatures.

In various embodiments, a reactor system may comprise multiple reaction chambers within a reactor to increase the output of the reactor system. Accordingly, reactor systems and methods in accordance with this disclosure may increase output of processed substrates (e.g., substrates with stacks of epitaxial layers deposited thereon), thus compensating for the slower processing and/or less output per reaction chamber caused be relatively lower processing temperatures. For example, a reactor comprising multiple reaction chambers (e.g., two, three, four or more reaction chambers) may provide the ability to conduct a commensurate number of processes within such reaction chambers (e.g., performing processing and/or producing processed substrates with desired deposited layers thereon in duplicate, triplicate, quadruplicate, or the like substantially simultaneously or at different times).

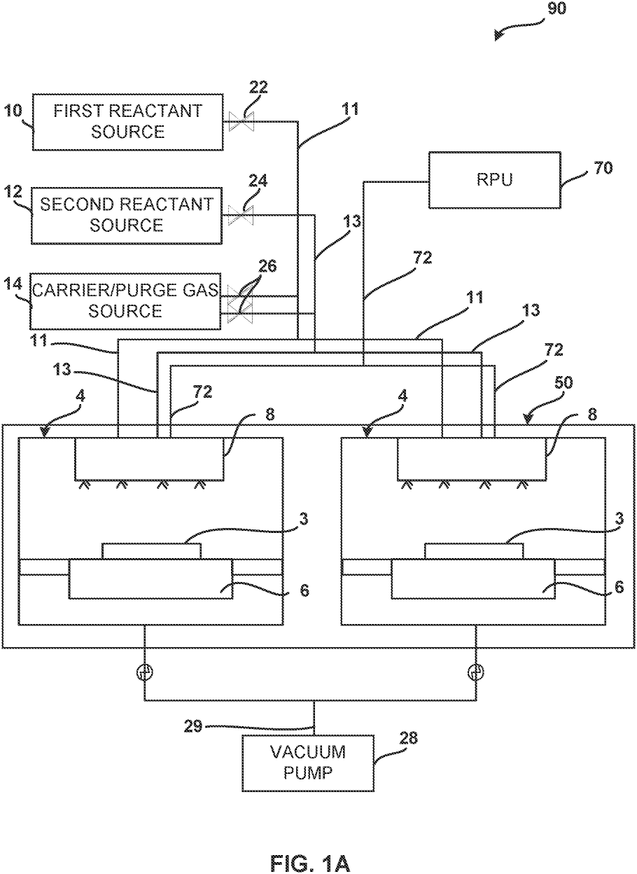

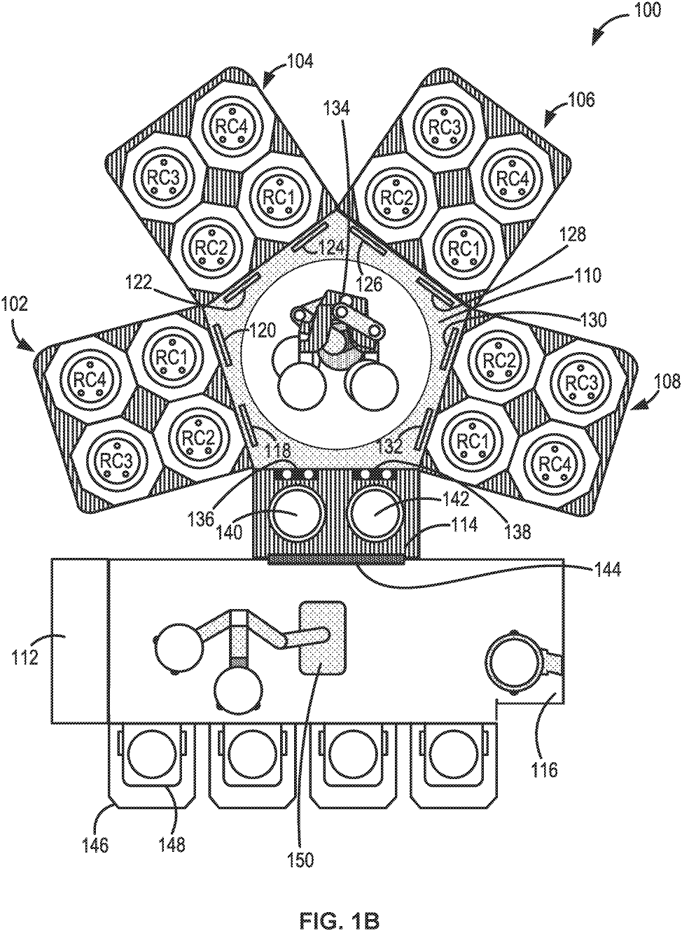

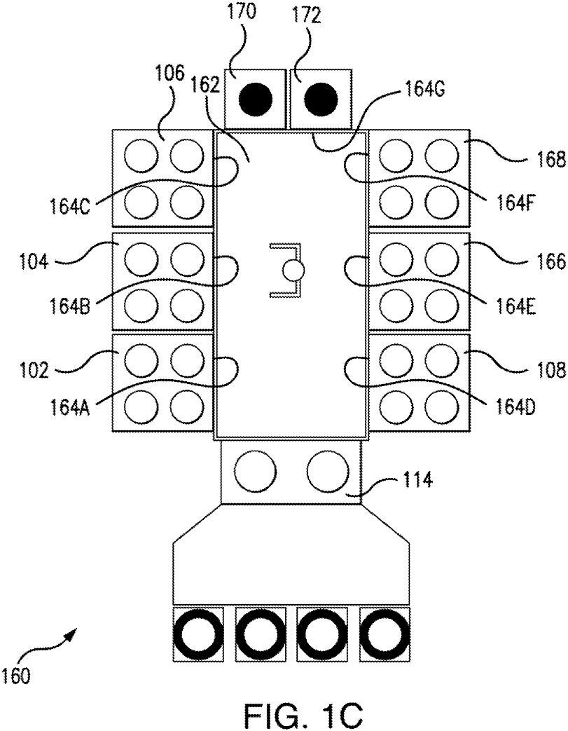

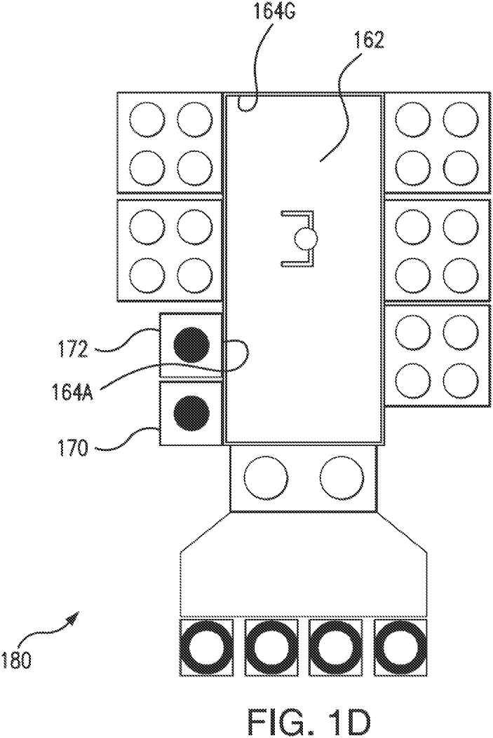

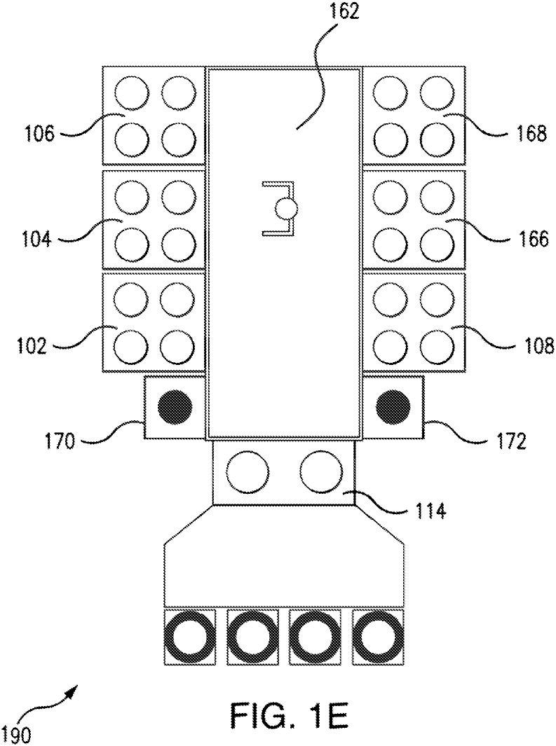

With reference to FIG. 1A, in various embodiments, a reactor system 90 may comprise a process module 50 comprising multiple reaction chambers 4. Reaction chambers 4 may be made of or comprise any suitable material, such as steel (e.g., stainless steel), a ceramic material, quartz, nickel, and/or the like. In various embodiments, the reaction space enclosed within each reaction chamber 4 may be lined and/or plated with any suitable material, such as nickel and/or quartz. Each reaction chamber 4 may comprise a susceptor 6 to hold a substrate 3 during processing, and a fluid distribution system 8 (e.g., a showerhead) to distribute one or more reactants to a surface of substrate 3. Reactor system 90 may comprise one or more reactant sources 10, 12 (i.e., gas sources), and/or a carrier and/or purge gas source 14, fluidly coupled to the multiple reaction chambers 4. Valves or controllers 22-26 may be configured to control the flow of the respective gases to reaction chambers 4.

Each gas source may be fluidly coupled to reaction chambers 4 by a shared gas line (i.e. a gas line that fluidly couples each gas source to multiple or all reaction chambers in a reactor system). For example, first reactant source 10 may be fluidly coupled to reaction chambers 4 (or reaction spaces enclosed therein) by first reactant shared line 11, and second reactant source 12 may be fluidly coupled to reaction chambers 4 (or reaction spaces enclosed therein) by second reactant shared line 13. In various embodiments, a reactor system may comprise any suitable number of reactant sources (e.g., a third reactant source, fourth reactant source, etc.) depending on the process, each of which may be fluidly coupled to the reaction chambers by a respective reactant shared line.

Carrier/purge gas source 14 may be fluidly coupled to first reactant shared line 11 and/or second reactant shared line 13, which fluidly couple carrier/purge gas source 14 to reaction chambers 4 (e.g., through which the carrier/purge gas may be co-flowed with one or more of the first reactant or the second reactant), or carrier/purge gas source 14 may be fluidly coupled to reaction chambers 4 by a purge gas shared line, which may be fluidly separate from first reactant shared line 11 and/or second reactant shared line 13. The shared lines between gas sources and the reaction chambers may allow provision of the respective gas to multiple or all reaction chambers 4 in a reactor system 90, either substantially simultaneously or at different times (different portions of the shared lines may comprise a valve coupled thereto that can be closed or opened to selectively provide gas to desired reaction chambers). System 90 may also comprise a vacuum source 28 fluidly coupled to the reaction chambers 4 by shared exhaust line 29.

The carrier/purge gas contained in, and delivered to reaction chambers 4 from, carrier/purge gas source 14 may be any suitable gas. In various embodiments, the carrier/purge gas maybe an inert gas (e.g., helium, argon, and/or nitrogen gas), and/or a gas such as hydrogen gas. In various embodiments, a reaction system 90 may comprise a remote plasma unit (RPU) 70. RPU 70 may be fluidly coupled to reaction chambers 4 by a plasma shared line 72. Plasma shared line 72 may allow provision of a plasma to multiple or all reaction chambers 4 in a reactor system 90, either substantially simultaneously or at different times (different portions of plasma shared line 72 may comprise a valve coupled thereto that can be closed or opened to selectively provide gas to desired reaction chambers). In various embodiments, RPU 70 may be fluidly coupled to first reactant shared line 11 and/or second reactant shared line 13 so that plasma may travel therethrough, for example, to clean first reactant shared line 11 and/or second reactant shared line 13.

In various embodiments, RPU 70 may generate activated species (e.g., radicals, plasma, and/or the like) from gases provided from the gas sources. The generated radicals may enter the reaction chambers 4 through showerheads 8 and then flow onto the substrates 3. A power used to form the plasma can range from about 10 W to about 5000 W. An RF frequency of the power can range from about 400 kHz to about 100 MHz. The generated radicals may be used, for example, to preclean the substrates 3 prior to deposition of a film or a material layers onto the substrates 3.

In accordance with various embodiments, FIG. 1B illustrates another exemplary reactor system 100. Reactor system 100 includes a plurality of process modules 102-108 (e.g., examples of process module 50 in FIG. 1A), a substrate handling chamber 110, a controller 112, a load lock chamber 114, and an equipment front end module 116. Process module 50 from FIG. 1A may be similar to one or more of process modules 102-108 of FIG. 1B. Accordingly, a gas source(s) may be coupled to the reaction chambers of any one process modules 102-108 similar to the coupling between the gas/reactant sources to reaction chambers 4 in reactor system 90 of FIG. 1A. In various embodiments, a gas source of reactor system 100 may be fluidly coupled to reaction chambers in different process modules 102-108 (e.g., by a gas shared line fluidly coupling the gas source to the respective reaction chambers).

In the illustrated example, each process module 102-108 can include multiple reaction chambers (e.g., four reaction chambers RC1-RC4). Unless otherwise noted, RC1-RC4 can be in any suitable order. Further, process modules in accordance with examples of the disclosure can include any suitable number of reaction chambers. Further, various process modules within a reactor system can be configured the same or differently.

In accordance with examples of the disclosure, at least one process module of a reactor system comprises multiple reaction chambers. For example, as shown in reactor system 100, at least one process module comprises a first reaction chamber RC1, a second reaction chamber RC2, a third reaction chamber RC3, and/or a fourth reaction chamber RC4.

In various embodiments, deposition of an epitaxial bilayer(s) or multiple layers or bilayers on a substrate may occur in one or more of the reaction chambers comprised in a process module. That is, multiple epitaxial layers may be deposited on a substrate in one reaction chamber. In various embodiments, different deposition or processing steps may occur in different reaction chambers (e.g., within a process module, or within reactor system 100). For example, a first reaction chamber RC1 in a process module may be configured to deposit a first epitaxial layer (e.g., comprising silicon germanium) on a substrate, and a second reaction chamber RC2 may be configured to deposit a second epitaxial layer (e.g., comprising silicon) on the substrate, for example, to form a silicon germanium/silicon bilayer or other silicon-doped/silicon layers. In such embodiments, a substrate may be transferred between the reaction chambers to receive the different deposition steps.

Substrate handling chamber 110 couples to each process module 102-108. By way of example, substrate handling chamber 110 can couple to each process module 102-108 via gate valves 118-132. In accordance with examples of the disclosure, process modules 102-108 can be coupled to and decoupled from substrate handling chamber 110.

Substrate handling chamber 110 can be used to move substrates between load lock chamber 114 and one or more process modules 102-108, and/or between process modules 102-108 (e.g., for different deposition or processing steps to be performed on a substrate). Substrate handling chamber 110 can include a back end robot 134. Back end robot 134 can transport substrates from load lock chamber 114 (e.g., stages 140, 142 therein) and any one of the susceptors within any of the reaction chambers. Back end robot 134 can be or include, for example, a multi joint robot. By way of example, back end robot 134 can retrieve and move a substrate to be transported using electrostatic or vacuum force. Back end robot 134 can be, for example, an end effector.

Controller 112 can be configured to perform one or more steps or functions as described herein. Controller 112 includes electronic circuitry and software to selectively operate valves, manifolds, heaters, pumps, and other components included in reactor system 100. Such circuitry and components operate to provide gases, regulate temperature, and the like to provide proper operation of reactor system 100. Controller 112 can include modules such as software and/or hardware components, which perform certain tasks. A module may be configured to reside on the addressable storage medium of the control system and be configured to execute one or more processes, such as a method described herein.

Load lock chamber 114 is connected to substrate handling chamber 110 via, for example, gate valves 136, 138 and to equipment front end module 116. Load lock chamber 114 can include one or more, e.g., two stages 140, 142 for staging substrates between equipment front end module 116 and substrate handling chamber 110.

Equipment front end module 116 is coupled to load lock chamber 114 via an opening 144. Front end module 116 can suitably include one or more load ports 146. Load ports 146 can be provided to accommodate a substrate carrier, such as a front opening unified pod (FOUP) 148. A robot 150 provided in the equipment front end module 116 can transport one or more (e.g., two at a time) substrates between FOUP 148 and the stages 140, 142 within load lock chamber 114.

In accordance with various embodiments, FIGS. 1C-E depict other exemplary reactor systems 160-190. As depicted in FIG. 1C, the reactor system 160 is similar to the reactor system 100 and additionally includes a substrate handling chamber 162 having a rectangular shape with eight facets 164A-164G. The first facet 164A connects the load lock chamber 114 to the substrate handling chamber 162. The second facet 164B, the third facet 164C, and the fourth facet 164 are longitudinally spaced from the first facet 164A and connect three deposition process modules, e.g., process modules 102-106, with the substrate handling chamber 162, and connect the first facet 164 to the eighth facet 164G. The fifth facet 164D, the sixth facet 164E, and the seventh facet 164F are parallel to the first-third facets 164A-164C, are laterally separated from the first-third facets 164A-164C by the back-end robot 134, and connect a further three deposition process modules, e.g., process modules 108, 166, and 168 to the substrate handling chamber 162. In the illustrated example two single reaction chambers 170-172, e.g., a first preclean process module and a second preclean process module, are connected to the load lock chamber 114 by the eight facet 164G.

Advantageously, in addition to the aforementioned productivity improvement associated with quadruplicate processing provided by the reactor system 100 (shown in FIG. 1B), the reactor system 160 provides flexibility. For example, precleaning may be accomplished in the single reaction chambers 170 and 172. Buffer layers may be processed in selected reaction chambers. And layers having similar (or identical) composition may be deposited using different process conditions in different process modules. For example, lower layer pairs in a SiGe/Si film stack may be deposited in the first-third process modules 102-106 using a process suited to process requirements peculiar to lower bilayers in SiGe/Si superlattices (e.g., process conditions advantageous to throughput in view of the relatively low risk of SiGe relaxation in lower bilayers), and upper layer pairs deposited in the fourth-sixth process modules 108 and 166-168 under process conditions selected to limit (or eliminate) risk of SiGe relaxation in layers in the upper portion of the superlattice. As will be appreciated by those of skill in the art, such deposition techniques may be advantageous in certain deposition operations, such as in the formation of so-called superlattices where deposition of the entirety of the superlattice under a common set of process conditions may not be practical and/or adjustment of process condition undesirable due to associated throughput reduction.

FIG. 1D depicts the reactor system 180. The reactor system 180 is similar to reactor system 160 (shown in FIG. 1C) and additionally includes single reaction chamber process modules 170 and 172. As depicted in FIG. 1D, the single reaction chamber process modules 170 and 172 are connected to the substrate handling chamber 110 at the first facet 164A. Advantageously, positioning the single reaction chambers 170 and 172 at the first facet 164A of the substrate handling chamber 162 can improve throughput by limiting the distance that the back-end robot 134 needs to move substrates entering the substrate handling chamber 162. In the example depicted in FIG. 1D the eighth facet 164G is vacant. As will be appreciated by those of skill in the art in view of the present disclosure, leaving the eighth facet vacant limits the footprint and thereby floor space occupied by the reactor system 180. As will be appreciated by those of skill in the art in view of the present disclosure, the single reaction chambers 170 and 172 may be connected to another of the facets of the substrate handling chamber 162 and remain within the scope of the present disclosure.

FIG. 1E depicts the reactor system 190. The reactor system 190 is similar to the reactor system 160 and additionally includes single chamber process modules 170 and 172 connected the substrate handling chamber 110 at facets located between the load lock chamber 114 and each of the deposition process modules 102-108 and 166-168. Positioning the single process modules 170 and 172 may be advantageous for processes where substrates move to either the first process module 102 or the fourth process module 166 following processing in process module 170 or the process module 172, for example, where substrates are precleaned immediately after entering the substrate handling chamber 110 and superlattices formed in stages using more than one of the process modules 102-108 and 166-168.

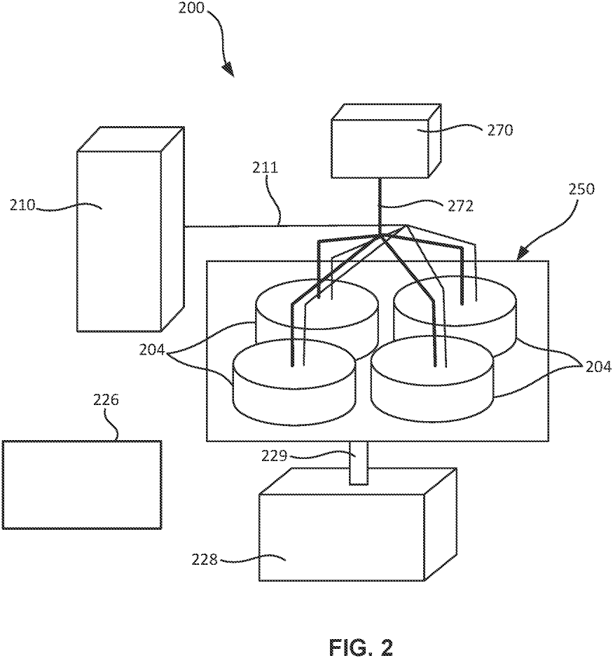

FIG. 2 depicts another embodiment of a reactor system 200 comprising a process module 250 having multiple reaction chambers 204 (four reaction chambers 204). Process module 250 may be an example of a processing module (102-108) of reactor system 100, depicted in FIG. 1B, discussed above. Reactor system 200 comprises a gas source 210 (which may house any number of gas sources for reactant gases, purge gases, carrier gases, and/or the like). Gas source 210 may be fluidly coupled to reaction chambers by shared gas line 211. Shared gas line 211 may allow provision of the respective gas to multiple or all reaction chambers 204 in a reactor system 200, either substantially simultaneously or at different times (different portions of the shared gas line may comprise a valve coupled thereto that can be closed or opened to selectively provide gas to desired reaction chambers 204). As depicted, reactor system 200 may be able to process four substrates at a time, whether substantially simultaneously (in quadruplicate) by delivering the same gases to all reaction chambers 204 at substantially the same time, or by running processes in each of reaction chambers 204, which may be at different stages or steps at different times. System 200 may also comprise a vacuum source 228 fluidly coupled to the reaction chambers 204 by shared exhaust line 229. Shared exhaust line 229 may be fluidly coupled to each of reaction chambers 204.

Similar to reactor system 90 in FIG. 1A, reactor system 200 may comprise RPU 270. RPU 270 may be fluidly coupled to reaction chambers 204 by plasma shared line 272. Plasma shared line 272 may allow provision of a plasma to multiple or all reaction chambers 204 in a reactor system 200, either substantially simultaneously or at different times (different portions of plasma shared line 272 may comprise a valve coupled thereto that can be closed or opened to selectively provide gas to desired reaction chambers). RPU 270 may have similar characteristics to those discussed in relation to RPU 70.

In various embodiments, reactor system 200 may comprise a controller 226 (similar to controller 112 in FIG. 1B), and a tangible, non-transitory memory configured to communicate with controller 226. The tangible, non-transitory memory may have instructions stored thereon that, in response to execution by controller 226, cause controller 226 to perform operations. In other words, controller 226 may comprise a processor programmed or otherwise configured to cause one or more method steps as described herein to be conducted. Controller 226 may be in communication with the various power sources, heating systems, pumps, robotics and gas flow controllers, or valves of the reactor, as will be appreciated by the skilled artisan. By way of example, controller 226 can be configured to perform the heating of heaters or susceptors, flowing of gases, opening or closing of gas lines, depositing, exposing, and/or post-deposition treatment steps of a method described herein.

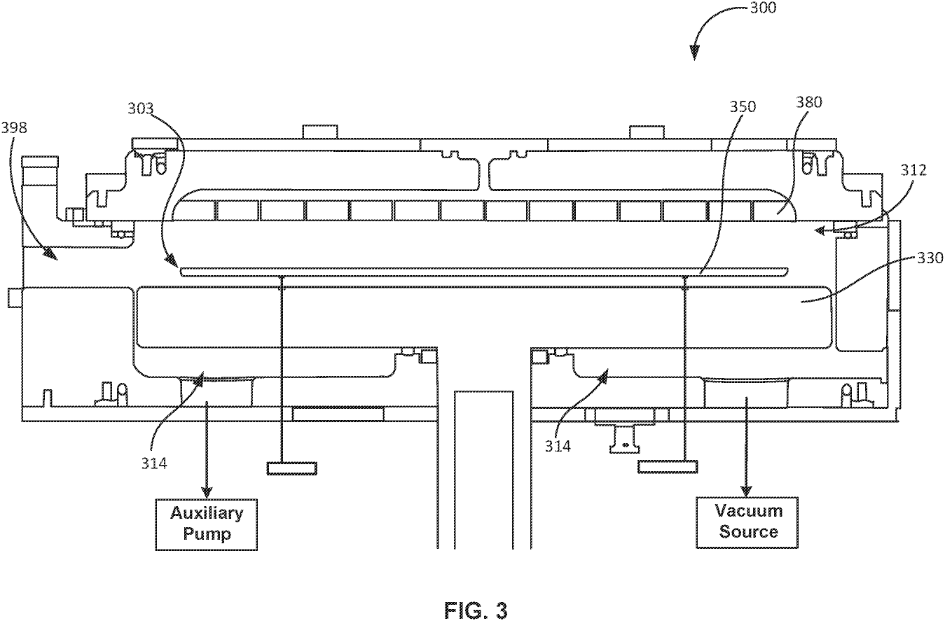

FIG. 3 depicts a more detailed figure of a reaction chamber 300 (an example of the reaction chambers of process modules 102-108 in reactor system 100 of FIG. 1B), in accordance with various embodiments. Reaction chamber 300 may comprise a reaction space 312 (i.e., an upper chamber), which may be configured for processing one or more substrates, and/or a lower chamber space 314 (i.e., a lower chamber). Lower chamber space 314 may be configured for the loading and unloading of substrates from the reaction chamber (e.g., through gate valve 398), and/or for providing a pressure differential between lower chamber space 314 and reaction space 312.

In various embodiments, susceptor 330 may move from loading position 303 to a processing position, thus moving substrate 350 into reaction space 312. Substrate 350 may be subsequently processed within the reaction chamber. For example, various gases or other compounds (e.g., reactants, purge gases, plasma or other activate species, and/or the like) may be flowed to reaction chamber 300, distributed into reaction space 312 by and through showerhead 380 (an example of gas distribution system 8 in FIG. 1A), and come in contact with substrate 350. In response, material deposition may occur on substrate 350.

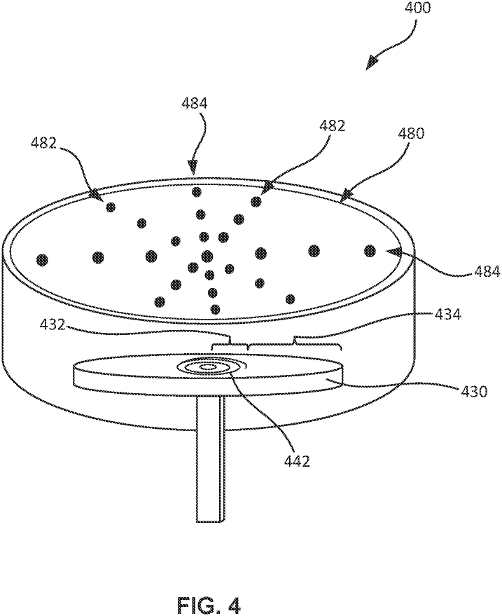

FIG. 4 depicts a schematic diagram of another reaction chamber 400 (another example of the reaction chambers of process modules 102-108 in reactor system 100 of FIG. 1B), in accordance with various embodiments. Reaction chamber 400 may be one of the reaction chambers in a multi-reaction chamber reactor system (e.g., reactor system 90 or 200). As discussed, reactor systems in accordance with various embodiments of this disclosure may be configured to process substrates and perform material deposition (e.g., epitaxial deposition) thereon at temperatures lower than typical elevated process temperatures (e.g., above 900° C.). Accordingly, with relative lower processing temperatures (e.g., between 300° C. and 660° C.), susceptor 430 (an example of susceptor 6 or 230) within reaction chamber 400 may comprise a ceramic material (rather than a metallic or graphite material required for said elevated temperatures). The ceramic material of susceptor 430 may be any suitable ceramic material, such as aluminum nitride, silicon carbide, silicon nitride, yttrium oxide, and/or the like. Such ceramic susceptors 430 for reaction chambers may be more cost-effective, thus allowing better cost-efficiency especially in light of slower processing temperature and the resulting slower and lower output of the systems and methods discussed herein.

In various embodiments, susceptors 430 may comprise a heater 442. Again, in response to the relatively lower processing temperatures of the current disclosure, heater 442 may be a resistive or electric heater. Such resistive heaters may be more cost-effective, thus allowing better cost-efficiency especially in light of slower processing temperature and the resulting slower and lower output of the systems and methods discussed herein. Heater 442 may be coupled to susceptor 430 in any suitable manner. For example, heater 442 may be comprised within susceptor 430. In various embodiments, a first heater (e.g., heater 442) may be disposed in a first susceptor portion 432 (which may be a radially inward portion of susceptor 430). A second heater may be disposed in a second susceptor portion 434. Thus, susceptor 430 may comprise a multi-zone heater (e.g., a dual-zone heater), such that different portions of susceptor 430 may be heated to different levels depending on the process and conditions thereof. In various embodiments, a susceptor may comprise more than two heaters, such that a susceptor may comprise a tri-zone heater, or a heater having more than three zones.

In various embodiments, showerhead 408 may comprise aluminum or an aluminum alloy. Such aluminum showerheads 480 may be more cost-effective than other materials, thus allowing better cost-efficiency especially in light of the lower processing temperature and the resulting slower and lower output of the systems and methods discussed herein. In various embodiments, showerhead 480 may comprise any suitable material, such as quartz, steel (e.g., stainless steel), nickel or a nickel-plated material, and/or the like. Quartz, stainless steel, and/or nickel materials may have the benefit of decreasing contamination or buildup within or on showerhead 480.

In various embodiments, the gas distribution systems (e.g., showerheads) comprised in the multi-reaction chamber reactor systems disclosed herein may comprise multiple channels to provide separate paths for various gases flowing to the reaction chamber. For example, showerhead 480 of reaction chamber 400 may comprise a first channel having voids 482, and a second channel having voids 484. Thus, showerhead 480 may be a dual-channel showerhead. The first channel and the second channel may be fluidly separate. With additional reference to FIG. 1A, suppose reaction chamber 400 is one of the reaction chambers 4 of reactor system 90. First reactant source 10 may be fluidly coupled to the first channel of showerhead 480, such that the first reactant enters reaction chamber 400 (and the reaction space therein) through first channel voids 482. Second reactant source 12 may be fluidly coupled to the second channel showerhead 480, such that the second reactant enters reaction chamber 400 (and the reaction space therein) through second channel voids 484. Accordingly, the first and second reactants may be flowed to reaction chamber 400 separately to mitigate the risk of interacting with one another prematurely, or otherwise in an undesirable manner, or causing contamination or build-up in a gas delivery line or showerhead.

In various embodiments, continuing with the example above, RPU 70 may be fluidly coupled to reaction chamber 400 through one or both of the first or second channels of showerhead 480. In response to RPU 70 being fluidly coupled to both the first and second channels of showerhead 480, plasma flowing from RPU 70 may be able to clean both the first and second channels.

In various embodiments, as discussed herein, a reactor system (e.g., reactor systems 100 and 200) may be configured for epitaxial layer deposition (e.g., by CVD). Accordingly, reactants may be configured to deposit silicon layers and/or silicon germanium layers on a substrate. Thus, the reactants for such deposition processes may comprise a silicon precursor and/or a germanium precursor.

In various embodiments, a silicon precursor may comprise silane, disilane, trisilane, chlorosilane, dichlorosilane, trichlorosilane, tetrachlorosilane, and/or tetraethylorthosilicate, or any other suitable compound. A germanium precursor may comprise a nonhalogenated germanium precursor, such as germane, digermane, trigermane, and/or the like, or a halogenated germanium precursor, such as germanium tetrachloride, germanium chlorohydride, germanium chlorobromide, and/or the like.

Without being bound by theory, silicon deposition (e.g., from a silicon precursor in a silicon layer) is affected or governed by temperature of the reaction chamber and components therein, while germanium deposition (e.g., from a germanium precursor in a silicon germanium layer) may be affected or governed by the flow volume or mass transport of the germanium precursor. Accordingly, taking such properties into consideration, the voids in a showerhead may be arranged to achieve a desired silicon and silicon germanium deposition on a substrate.

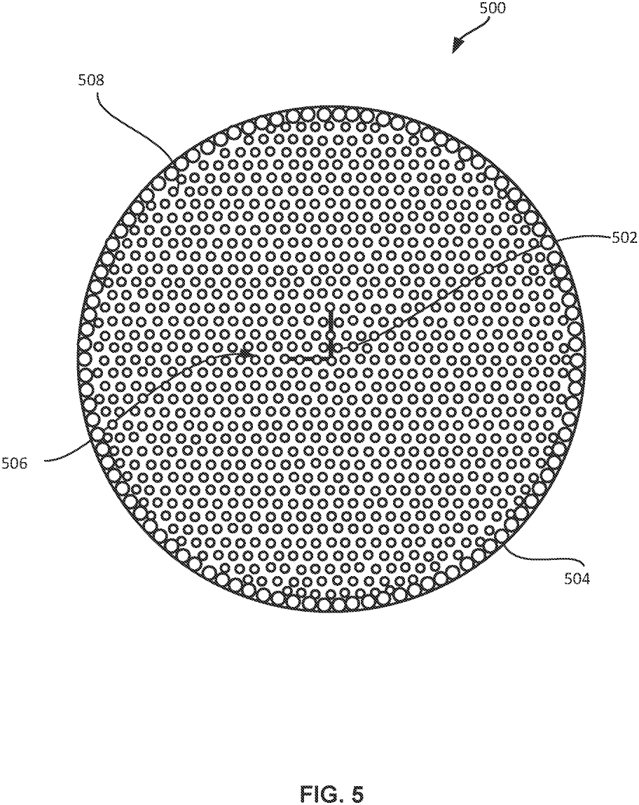

FIG. 5 depicts a bottom section 500 of a showerhead (e.g., showerhead 8 in FIG. 1A, or showerhead 480 in FIG. 4). Bottom section 500 includes a center region 506, including a plurality of holes 502, and an outer region 508, including a plurality of holes 504. Center region 506 can include about 10 percent to about 99 percent, about 25 percent to about 75 percent, or about 75 percent to about 99 percent of a bottom surface of bottom section 500 (e.g., measured radially from a center of bottom section 500), with outer region 508 including the remaining space of bottom section 500. In various embodiments, the outer region can include the outer most ring of holes 504. The holes can be configured as, for example, concentric rings of holes. In various embodiments, a diameter of holes 504 in outer region 508 ranges from about 1 mm to about 3 mm, about 1.5 to about 2.5 mm, or about 1.8 mm to about 2.2 mm. A diameter of holes 502 in center region 506 can range from about 0.5 mm to about 1.5 mm, about 0.75 to about 1.25 mm, or about 0.8 mm to about 1.2 mm. In various embodiments, the diameter of holes 504 in outer region 508 may be larger than the diameter of holes 502 in center region 506.

In various embodiments, bottom section 500 can, in addition to or in lieu of having holes of different sizes, have various hole densities in regions extending radially from a center of bottom section 500. For example, a density of holes can increase (e.g., linearly, geometrically, or the like) from a center of bottom section 500 to an outer edge of bottom section 500. The density of holes can be designed to provide desired species distribution.

In various embodiments including a multi-channel showerhead, a greater number of holes in the outer region of a showerhead may be in fluid communication with a germanium precursor source than holes in the outer region of the showerhead in fluid communication with a silicon precursor. The outer region having, for example, a greater hole density and/or larger holes, may allow greater flow of the germanium precursor to achieve desired deposition of a silicon germanium layer.

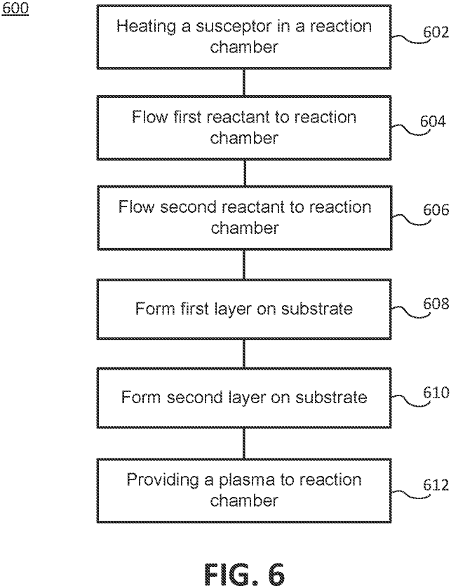

With reference to FIG. 6, a method 600 of performing a multilayer deposition process on a substrate (e.g., to deposit epitaxial layers) is depicted. With additional reference to FIGS. 1 and 4, in various embodiments, susceptor(s) 6 may be heated within a reaction chamber (step 602). As discussed herein, heater 442 may be a resistive heater (e.g., an electric heater). Heater may be coupled to susceptor 430 in any suitable manner. For example, heater 442 may be incorporated into, or at least partially enclosed within, susceptor 430. Heating may accomplished by heating the substrate to a preclean temperature, removing material from a surface of the substrate in-situ by flowing preclean process gases through the showerhead, and thereafter heating the substrate to a deposition temperature, and thereafter depositing a material layer onto the substrate by flowing one or more precursors through the showerhead. As will be appreciated by those of skill in the art in view of the present disclosure, precleaning substrates in-situ (i.e. in the same process chamber used for layer deposition) can increase throughput by limiting transfers of substrates through the substrate handling chamber 110 (shown in FIG. 1B). As will also be appreciated by those of skill in the art in view of the present disclosure, precleaning substrates in-situ can also eliminate the need to bake substrates within the process chambers prior to layer deposition by avoiding exposure to moisture that may be resident within the substrate handling chamber 110 subsequent to precleaning the substrates. It is also contemplated that substrates may be cleaned ex-situ, e.g., in the single chamber process module 170 (shown in FIG. 1C) or the single chamber process module 172 (shown in FIG. 1C).

In various embodiments, as discussed herein, processing of substrates for epitaxial layer deposition may occur at temperatures lower than typical elevated processing temperatures (e.g., elevated temperatures in excess of 900° C.). For example, the susceptor and/or reaction chamber may be heated to a temperature between 300° C. and 660° C., or between 400° C. and 600° C., or between 400° C. and 500° C., or between 475° C. and 550° C., or between 475° C. and 500° C. Such lower processing temperatures (relative to typical elevated temperatures discussed herein), allow deposition of multiple epitaxial layers on top of one another sequentially, without thermally degrading or otherwise decomposing already-deposited layers on the substrate. Additionally, in relation to deposition of silicon germanium/silicon bilayers, processing temperature may be important to maintain a desired crystalline structure between the silicon germanium layers and silicon layers. Because silicon germanium layers have a different crystal lattice than silicon layers, in order to preserve crystal quality through the layer stack and avoid defects, it may be desirable to have the crystal lattice remain strained throughout processing. Relaxation of the strain between the crystal lattice in the layers may decrease crystal quality and cause dislocation defects in the crystal lattice, which can propagate through a portion of, or the entire, epitaxial layer stack. Such lower processing temperatures discussed herein (e.g., temperatures between 300° C. and 660° C., or between 400° C. and 550° C.), may mitigate the risk of strain relaxation between epitaxial layers and the associated defects, whereas elevated processing temperatures may increase such risks.

In various embodiments, a first reactant may be flowed to reaction chamber(s) 4 (step 604) from a first reactant source 10. The first reactant may be a first epitaxial semiconductor reactant. For example, the first reactant may be a silicon precursor, such as those discussed herein. First reactant source 10 may be configured to house and/or deliver the first reactant to the reaction chamber(s) 4. The first reactant may be flowed from first reactant source 10 to reaction chamber(s) 4 through first reactant shared line 11. Therefore, the first reactant may be flowed to multiple reaction chambers 4, if desired. In various embodiments, a controller (e.g., controller 226 of reactor system 200 in FIG. 2) may flow the first reactant from first reactant source 10 to reaction chambers 4, for example, by opening a valve on first reactant shared line 11. In various embodiments, the controller may also control to which reaction chamber 4 the first reactant may flow. For example, a valve may be coupled to each leg of first reactant shared line 11 going to a different reaction chamber 4, and each respective valve may be open or closed (e.g., by the controller) depending on whether the first reactant will be flowed to the respective reaction chamber 4.

In various embodiments, a second reactant may be flowed to reaction chamber(s) 4 (step 606) from a second reactant source 12. The second reactant may be a second epitaxial semiconductor reactant. For example, the second reactant may be a germanium precursor, such as those discussed herein. Second reactant source 12 may be configured to house and/or deliver the second reactant to the reaction chamber(s) 4. The second reactant may be flowed from second reactant source 12 to reaction chamber(s) 4 through second reactant shared line 13. Therefore, the second reactant may be flowed to multiple reaction chambers 4, if desired. In various embodiments, the controller of the reactor system may flow the second reactant from second reactant source 12 to reaction chambers 4, for example, by opening a valve on second reactant shared line 13. In various embodiments, the controller may also control to which reaction chamber 4 the second reactant may flow. For example, a valve may be coupled to each leg of second reactant shared line 13 going to a different reaction chamber 4, and each respective valve may be open or closed (e.g., by the controller) depending on whether the second reactant will be flowed to the respective reaction chamber 4.

In various embodiments, in response to flowing the first reactant (step 604) and flowing the second reactant (step 606), a first layer may be formed on substrate(s) 30. The first layer may be a first epitaxial layer. The first reactant and second reactant may be flowed to the reaction chamber(s) 4 at different times or at substantially the same time to form the first layer on substrate(s) 30. As discussed herein, the first reactant may flow through a first channel in showerhead(s) 480, and the second reactant may flow through a second channel of showerhead(s) 480 into the reaction space(s) of reaction chamber(s) 4. As discussed herein, the germanium precursor may be applied to a greater extent in an outer region of showerhead(s) 480 and/or reaction chamber(s) 4 than the silicon precursor by the arrangement of first channel holes versus second channel holes. In various embodiments, the first layer formed (step 608) on substrate(s) 30 may be a silicon germanium layer formed from a silicon precursor and a germanium precursor, as discussed herein.

In various embodiments, a silicon germanium layer may comprise between 20-25% by weight germanium (i.e., a silicon germanium layer may comprise a germanium concentration of 20-25%).

In various embodiments, in response to flowing the first reactant (step 604), a second layer may be formed on substrate(s) 30 (step 610). The second layer may be a second epitaxial layer deposited on top of the first epitaxial layer. The first layer and the second layer, together, may be a bilayer (e.g., a silicon germanium/silicon bilayer). To form the second layer on top of the first layer, the first precursor may be flowed again to the reaction chamber(s) 4 (i.e., repeating step 604 for step 610, thus providing a separate step 604 for each of forming the first layer and forming the second layer). That is, flowing the first reactant to the reaction chamber (step 604) may be performed to form the first layer on the substrate (step 608), and performed again separately to form the second layer on the substrate (step 610). To form the second layer, the first reactant may be flowed to the reaction chamber (step 604) without step 606 occurring. Thus step 604 may be repeated as necessary to create the silicon germanium layer and the silicon layer in order to form a bilayer.

In various embodiments, the steps of method 600 (e.g., steps 604-610) may be repeated, as appropriate, to create as many bilayers as desired. For example, the systems and methods disclosed herein may be configured to form 32 or more bilayers on a substrate, thus, for example, repeating the steps of method 600, as appropriate, 32 times (which may include repeating step 604 64 times, and repeating steps 606, 608, and 610 32 times). In various embodiments, the steps of 600 may be repeated as appropriate to form up to 196 bilayers. In various embodiments, subsets of the 196 bilayers may be formed in different process modules, for example, using different process conditions to form compositionally similar (or identical) bilayers in the different process modules.

In various embodiments, the numerous bilayers may be formed within each reaction chamber 4 without removing the substrate from the respective reaction chamber 4. In various embodiments, individual layer thicknesses for the first and/or second layers deposited on a substrate may be between 20 to 80 nanometers, or between 20 and 25 nanometers. In various embodiments, a film stack comprising the numerous bilayers may comprise a thickness of between 1.3 to 1.6 micrometers.

The reaction chambers 4 may be cleaned at any suitable time. In various embodiments, reaction chambers 4 may be cleaned (only) after the desired number of bilayers are formed on a substrate. For example, after the 32 or more bilayers are formed on substrate 3, a plasma may be provided to reaction chamber(s) 4 (step 612). The plasma may clean reaction chambers 4 and the components therein. Cleaning reaction chamber(s) 4 only after several bilayers have been deposited can help to speed up processing and save resources relative to cleaning reaction chamber(s) 4 more often. Thus, such cleanings may be more cost-effective, thus allowing better cost-efficiency especially in light of slower processing temperature and the resulting slower and lower output of the systems and methods discussed herein.

The plasma may be provided from RPU 70 to reaction chambers 4 though plasma shared line 72. The plasma may be formed from a gas (e.g., nitrogen trifluoride, oxygen gas, hydrogen gas, and/or the like) by applying plasma power. As discussed herein, RPU 70 may be fluidly coupled to the first channel and/or second channel in a showerhead 8, such that the plasma from RPU 70 may clean one or both channels within a showerhead. In various embodiments, cleaning of a reaction chamber may comprise providing a plasma to the reaction chamber (step 612) formed from hydrogen gas (H₂ plasma). Such cleaning occurring before a multilayer deposition process begins or occurs may avoid a need to bake substrates in the reaction chambers 4 in order to drive off contaminants that may have been received in a wafer or substrate transfer chamber. Such cleaning may allow for the use of ceramic heaters/susceptors because there is no need for elevated baking temperatures in the reaction chambers, which ceramic/susceptors may not be able to withstand.

Examples of the methods in accordance with this disclosure.

### Example 1

At a processing temperature of about 660° C. and pressure of about 20 Torr, the following steps occurred to form a silicon germanium epitaxial layer: providing between 15 and about 45 standard liters per minute (slm) hydrogen gas (H₂), between about 10 and about 35 standard cubic centimeters per minute (sccm) silane gas (SiH4), between about 20 and about 65 sccm dichlorosilane gas (SIH₂Cl₂), between about 20 and about 80 sccm hydrogen chloride gas (HCl), and between about 20 and about 60 sccm germane gas (GeH₄) to a reaction chamber, with a deposition time of between about 10 and about 70 seconds, to form a silicon germanium layer; and providing between about 15 and about 45 slm hydrogen gas and between about 100 and about 310 sccm silane gas to a reaction chamber, with a deposition time of between about 10 and about 60 seconds, to form a silicon layer. Therefore, the total time to form a silicon germanium/silicon bilayer may be between about may be between about 20 second about 130 seconds.

### Example 2

At a processing temperature of about 550° C. and pressure of about 20 Torr, the following steps occurred to form a silicon germanium epitaxial layer: providing between about 15 and about 45 slm hydrogen gas, between about 14 and about 42 sccm disilane gas (Si₂H₆), between about 60 and about 180 sccm germane gas to a reaction chamber, with a deposition time of between about 12 and about 60 seconds, to form a silicon germanium layer; and providing between about 15 and about 45 slm hydrogen gas and between about 10 and about 70 sccm disilane gas to a reaction chamber, with a deposition time of between about 20 and about 110 seconds, to form a silicon layer. Therefore, the total time to form a silicon germanium/silicon bilayer may be between about 30 seconds and about 170 seconds.

### Example 3

At a processing temperature of about 550° C. and pressure of about 10 Torr, the following steps occurred to form a silicon germanium epitaxial layer: providing between about 15 and about 45 slm hydrogen gas, between about 7 and about 21 sccm disilane gas (Si₂H₆), between about 80 and about 200 sccm germane gas to a reaction chamber, with a deposition time of between about 20 and about 55 seconds, to form a silicon germanium layer; and providing between about 15 and about 45 slm hydrogen gas and between about 10 and about 35 sccm disilane gas to a reaction chamber, with a deposition time of between about 50 seconds and about 310 seconds, to form a silicon layer. Therefore, the total time to form a silicon germanium/silicon bilayer may be between about between about 70 seconds and about 365 seconds.

In view of Examples 1-3 above, with processing temperatures decreasing to about 550° C., the deposition time to form a silicon germanium/silicon bilayer increased. As discussed herein, the lower processing temperatures may mitigate the risk of strain relaxation within the crystal lattice of the bilayer(s). However, such lower processing temperatures and slower deposition decreases output for epitaxial layers and devices. Thus, the systems and methods discussed herein implementing higher-capacity and cost-effective components and methods may be beneficial in compensating for the longer and/or slower processing and deposition times.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the subject matter disclosed herein. Thus, discussion of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize that the subject matter of the present application may be practiced without one or more of the specific features or advantages of a particular embodiment. In other instances, additional features and advantages may be recognized in certain embodiments that may not be present in all embodiments of the disclosure. Further, in some instances, well-known structures, materials, or operations are not shown or described in detail to avoid obscuring aspects of the subject matter of the present disclosure. No claim element is intended to invoke 35 U.S.C. 112(f) unless the element is expressly recited using the phrase “means for.”

The scope of the disclosure is to be limited by nothing other than the appended claims, in which reference to an element in the singular is not intended to mean “one and only one” unless explicitly so stated, but rather “one or more.” It is to be understood that unless specifically stated otherwise, references to “a,” “an,” and/or “the” may include one or more than one and that reference to an item in the singular may also include the item in the plural. Further, the term “plurality” can be defined as “at least two.” As used herein, the phrase “at least one of”, when used with a list of items, means different combinations of one or more of the listed items may be used and only one of the items in the list may be needed. The item may be a particular object, thing, or category. Moreover, where a phrase similar to “at least one of A, B, and C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A, B, and C. In some cases, “at least one of item A, item B, and item C” may mean, for example, without limitation, two of item A, one of item B, and ten of item C; four of item B and seven of item C; or some other suitable combination.

All ranges and ratio limits disclosed herein may be combined. Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Any reference to attached, fixed, connected or the like may include permanent, removable, temporary, partial, full and/or any other possible attachment option. Additionally, any reference to without contact (or similar phrases) may also include reduced contact or minimal contact. In the above description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A reactor system, comprising:
a reactor, comprising:
a first reaction chamber comprising a first reaction space enclosed therein, a first susceptor disposed within the first reaction space, and a first fluid distribution system in fluid communication with the first reaction space, wherein the first susceptor is configured to support a first substrate; and
a second reaction chamber comprising a second reaction space enclosed therein, a second susceptor disposed within the second reaction space, and a second fluid distribution system in fluid communication with the second reaction space, wherein the second susceptor is configured to support a second substrate; and
a first epitaxial semiconductor reactant source, wherein the first reaction chamber and the second reaction chamber are fluidly coupled to the first epitaxial semiconductor reactant source at least partially by a first reactant shared line,
wherein the reactor system is configured to deliver a first epitaxial semiconductor reactant from the first epitaxial semiconductor reactant source to the first reaction chamber and a second reaction chamber through the first reactant shared line.

2. The reactor system of claim 1, wherein the first susceptor and the second susceptor comprise a ceramic material.

3. The reactor system of claim 2, wherein the first susceptor and the second susceptor each comprise an electric heater.

4. The reactor system of claim 3, wherein the first susceptor and the second susceptor each comprise a first heater in a first susceptor portion and a second heater in a second susceptor portion, such that the first susceptor and the second susceptor comprise dual-zone heaters.

5. The reactor system of claim 1, further comprising a remote plasma unit in fluid communication with the first reaction chamber and the second reaction chamber, wherein the remote plasma unit is configured to deliver an activated species to the first reaction chamber and a second reaction chamber through a shared plasma line.

6. The reactor system of claim 5, further comprising:
a second epitaxial semiconductor reactant source, wherein the first reaction chamber and the second reaction chamber are fluidly coupled to the second epitaxial semiconductor reactant source at least partially by a second reactant shared line.

7. The reactor system of claim 6, wherein the first fluid distribution system and the second fluid distribution system each comprise a first channel fluidly coupled to the first epitaxial semiconductor reactant source and a second channel fluidly coupled to the second epitaxial semiconductor reactant source, wherein the first channel and the second channel are fluidly separate.

8. The reactor system of claim 7, wherein the remote plasma unit is fluidly coupled to the first channel and the second channel in each of the first fluid distribution system and the second fluid distribution system.

9. The reactor system of claim 7, wherein the first epitaxial semiconductor reactant source is a silicon-containing epitaxial semiconductor reactant source configured to deliver a silicon precursor to the first reaction chamber and the second reaction chamber, and wherein the second epitaxial semiconductor reactant source is a germanium-containing epitaxial semiconductor reactant source configured to deliver a germanium precursor to the first reaction chamber and the second reaction chamber.

10. The reactor system of claim 6, further comprising:
a controller; and
a tangible, non-transitory memory configured to communicate with the controller, the tangible, non-transitory memory having instructions stored thereon that, in response to execution by the controller, cause the controller to perform operations comprising:
flowing, by the controller, a first epitaxial semiconductor reactant from the first epitaxial semiconductor reactant source to the first reaction chamber and the second reaction chamber via the first reactant shared line;
flowing, by the controller, a second epitaxial semiconductor reactant from the second epitaxial semiconductor reactant source to the first reaction chamber and the second reaction chamber via the second reactant shared line;
forming a first epitaxial layer on the first substrate; and
forming a second epitaxial layer on the second substrate.

11. The reactor system of claim 9, wherein the silicon precursor comprises at least one of a hydrogenated silicon precursor or a chlorinated silicon precursor.

12. The reactor system of claim 11, wherein the germanium precursor comprises at least one of germane (GeH₄), digermane (Ge₂H₆), trigermane (Ge₃H₈), or germylsilane (GeH₆Si).

13. The reactor system of claim 9, wherein the second channel comprises a greater number of holes at an outer portion of each of the first fluid distribution system and the second fluid distribution system than the first channel.

14. The reactor system of claim 1, wherein the first fluid distribution system and the second fluid distribution system comprise at least one of aluminum, quartz, stainless steel, or nickel.

15. The reactor system of claim 1, further comprising:
a substrate handling chamber having a rectangular shape connected to the reactor;
a load lock chamber connected to the substrate handling chamber and therethrough to the reactor;
a single chamber reactor connected to the substrate handling chamber and
wherein the single chamber reactor is between the load lock chamber and the reactor, or wherein the reactor is between the load lock chamber and the single chamber reactor.

16. A method, comprising:
performing a multilayer deposition process on a first substrate in a first reaction chamber and on a second substrate in a second reaction chamber, wherein the first reaction chamber and the second reaction chamber are comprised in a reactor, wherein the multilayer deposition process comprises steps, including:
flowing a first epitaxial semiconductor reactant from a first epitaxial semiconductor reactant source to the first reaction chamber and the second reaction chamber through a first reactant shared line fluidly coupling the first epitaxial semiconductor reactant source to the first reaction chamber and the second reaction chamber;
flowing a second epitaxial semiconductor reactant from a second epitaxial semiconductor reactant source to the first reaction chamber and the second reaction chamber through a second reactant shared line fluidly coupling the second epitaxial semiconductor reactant source to the first reaction chamber and the second reaction chamber;
forming a first epitaxial layer on the first substrate and on the second substrate; and
forming a second epitaxial layer on the first substrate and on the second substrate.

17. The method of claim 16, wherein the forming the first epitaxial layer occurs in response to the flowing the first epitaxial semiconductor reactant and the flowing the second epitaxial semiconductor reactant to the first reaction chamber and the second reaction chamber,
wherein the first epitaxial semiconductor reactant comprises a silicon precursor,
wherein the second epitaxial semiconductor reactant comprises a germanium precursor, and
wherein the first epitaxial layer comprises a silicon-germanium layer.

18. The method of claim 17, wherein the forming the second epitaxial layer occurs in response to the flowing the first epitaxial semiconductor reactant to the first reaction chamber and the second reaction chamber separately from the flowing the second epitaxial semiconductor reactant to the first reaction chamber and the second reaction chamber,
wherein the first epitaxial semiconductor reactant comprises the silicon precursor, and
wherein the second epitaxial layer comprises a silicon layer.

19. The method of claim 18, wherein the multilayer deposition process is repeated a plurality of times, wherein the plurality of times is at least 32 times.

20. The method of claim 19, further comprising flowing a cleaning compound from a remote plasma unit to the first reaction chamber and the second reaction chamber, wherein the remote plasma unit is fluidly coupled to the first reaction chamber and the second reaction chamber at least partially by a shared plasma line, and wherein the flowing the cleaning compound occurs after the multilayer deposition process is repeated the plurality of times.

21. The method of claim 16, further comprising:
precleaning the first substrate in the first reaction chamber;
heating a first susceptor within the first reaction chamber to a temperature between 475° C. and 550° C., wherein the first susceptor supports the first substrate; and
heating a second susceptor within the second reaction chamber to a temperature between 475° C. and 550° C., wherein the second susceptor supports the second substrate.
